(19) United States
(12) Patent Application Publication
(10) Pub. No.: US 2002/0173099 A1
(43) Pub. Date: Nov. 21, 2002

(54) METHOD FOR FABRICATING A MOS TRANSISTOR OF AN EMBEDDED MEMORY

(76) Inventors: Horng-Nan Chern, Tainan Hsien (TW); Kun-Chi Lin, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/858,518

(22) Filed: May 17, 2001

(51) Int. Cl. H01L 21/336

(52) U.S. Cl. 438/257; 438/258

(57) ABSTRACT

The present invention explains a method for manufacturing a MOS transistor of an embedded memory. The method of present invention is to first define a memory array area and a periphery circuit region on the surface of the semiconductor wafer followed by forming each gate, a spacer of each gate, and lightly doped drain (LDD) in memory array area. A stop layer and a dielectric layer are formed on the surface of semiconductor. Then, the dielectric layer in periphery circuit regions is removed followed by forming each gate in the periphery circuit regions. Lightly doped drain (LDD) adjacent each gate and on sidewalls of gate, a spacer, a source, and a drain are formed in periphery circuit regions. Finally, a self-aligned silicide (salicide) process is performed for forming a silicide layer on the surface of each gate, source and drain.

### BACKGROUND OF THE INVENTION

1. Field of the Invention

The present invention relates to a method for fabricating a metal oxide semiconductor (MOS) transistor of an embedded memory.

2. Description of Prior Art

With increasing semiconductor integration, the present trend of manufacturing semiconductor integrated circuits involves integrating memory cell arrays and high-speed logic circuit elements onto a single chip forming a so-called embedded memory. An embedded memory reduces the circuit area and increases the signal processing speed. Logic circuits elements are also called periphery circuit region.

The MOS transistors formed in the periphery circuit region need to have low resistance and high speed. To fit these requirements, the present semiconductor process primarily uses a self-alignment silicide (salicide) process for forming a silicide layer on each gate, source and drain of the MOS transistors formed on the periphery circuit region. Performing the process reduces the surface resistance of each gate, source and drain of the MOS transistors.

The self-aligned-contact (SAC) process developed for solving the electrical connection problem of memory cells in the memory array area involves forming a silicon nitride layer, as a cap layer, and a spacer on the top and side surfaces of a gate of a pass transistor formed in the memory array area as an isolation mask in the subsequent SAC process.

The problem is the inability to simultaneously perform both the above processes, so that the prior arts provide two methods for solving this problem. One method based on periphery circuits regions of self-aligned-contact (SAC) process increases the junction leakage current which can cause a more rapid loss of charge in the capacitor, which may adversely affect storage charge refresh times. The other method based on memory increases surface resistance of each gate, source and drain of periphery circuits regions for decreasing access speed.

Please refer to FIG. 1 to FIG. 5. FIG. 1 to FIG. 5 of schemtaic diagrams of a prior art for fabricating a metal-oxide-semiconductor (MOS) transistor of an embedded memory on a semiconductor wafer 10. As shown in FIG. 1, the surface of the silicon substrate 12 is divided into a memory array area 14 and a periphery circuit region 16. The memory array area 14 comprises a cell well 18, and the periphery circuit region 14 comprises at least one N-well 20 and at least one P-well 22. Each region is separated by several shallow trench isolation structures 23.

The prior art method first involves forming a gate oxide layer 21, a polysilicon layer 24, a polycide layer 26 and a cap layer 28 composed of silicon nitride, respectively, on the surface of the semiconductor wafer 10. As shown in FIG. 2, a photoresist layer 30 is formed above the cap layer 28 followed by performing a lithographic process for simultaneously defining the gate patterns of the memory array area 14 and the periphery circuit region 16 in the photoresist layer 30. Thereafter, the patterned photoresist layer 30 is used as a mask layer to perform an etching process for removing the cap layer 28, the polycide layer 26 and the polysilicon layer 24 down to the surface of the gate oxide layer 21. The process above forms a plurality of gates 32 on the cell well 18 of the memory array area 14 and a plurality of gates 34 above both the N-well 20 and the P-well 22 of the periphery circuit region 16 at the same time.

As shown in FIG. 3, the photoresist layer 30 above the cap layer 28 is completely removed followed by performing an ion implantation process for forming a doped region (not shown) on the surface of the silicon substrate 12 on two sides of the gates 32, 34. Thereafter, a rapid thermal process (RTP) drives dopants in the doped region into the silicon substrate 12 so as to form lightly doped drains (LDD) 36 of each MOS transistor.

As shown in FIG. 4, a silicon nitride layer (not shown) is deposited on the semiconductor wafer 10. An an-isotropic etching process is performed subsequently for etching back portions of the silicon nitride layer to form a spacer 38 around each gate 32, 34 of the memory array area 14 and the periphery circuit region 16 respectively. Then, an ion implantation process is performed for forming a source and drain of each MOS transistor in the periphery circuit region 16. A photoresist layer (not shown) is formed for covering the memory array area 14 and gates 32, 34 of the N-well 20 followed by implanting N-type dopants to the surface of the P-well 22 so as to form a doped region 42 and subsequently removing the photoresist layer. Following this, another photoresist layer (not shown) is formed to completely cover the memory array area 14 and the gate 34 of the P-well 22. Then, P-type dopants are used to implant the N-well 20 of the periphery circuit region 16 so as to form a doped region 40. Thereafter, a rapid thermal process is used to drive dopants of each doped region 40, 42 into the silicon substrate 12 so as to form the source and the drain of each MOS transistor in the periphery circuit region 16.

As shown in FIG. 5, a salicide block (SAB) layer 44 is formed on the silicon substrate 12 of the memory array area 14. Then, a self-aligned silicide process is performed in the periphery circuit region 16 for forming a salicide layer 46 on the surface of each source and drain so as to finish the process of manufacturing a MOS transistor of an embedded memory according to the prior art.

The prior art method simultaneously forms the cap layer 28 in the memory array area and the periphery circuit region, so as to perform a self-aligned-contact (SAC) process in the periphery circuit region to increase surface resistance of the MOS gate and decrease access speed.

### SUMMARY OF THE INVENTION

It is therefore a primary object of the present invention to provide a method of manufacturing a MOS transistor of an embedded memory for solving the above mentioned problem.

The present invention provides a method for manufacturing a MOS transistor of an embedded memory. The method of the present invention involves first defining a memory array region and a periphery circuit region on the semiconductor wafer followed by forming a first dielectric layer, a doped polysilicon layer, a passivation layer, and a first photoresist layer. A first photolithographic process is performed so as to define a plurality of gate patterns in the first photoresist layer above the memory array area. The gate patterns in the first photoresist layer are used as a hard mask to etch the passivation layer and the doped polysilicon layer located both in the memory array area and in the periphery circuit region for forming each gate in the memory array area. A spacer is formed on sidewalls of each gate in the memory array area and a lightly doped drain (LDD) is formed adjacent to each gate in the memory array area. A stop layer and a second dielectric layer are formed in sequence on the surface of the semiconductor wafer followed by performing an etch-back process to remove the second dielectric layer and the stop layer located in the periphery circuit region. Then, an undoped polysilicon layer and a second photoresist layer are formed in sequence on the surface of the semiconductor wafer. A second photolithographic process is performed to define a plurality of gate patterns in the second photoresist layer above the periphery circuit region. The gate patterns of the second photoresist layer are used as a hard mask to etch the undoped polysilicon layer for forming each gate in the periphery circuit region. Thereafter, lightly doped drains (LDD) adjacent to each gate, a spacer, a source and a drain are respectively formed in the periphery circuit region. Finally, a self-aligned silicide (salicide) process is performed to form a metal silicide layer respectively on the top surface of each gate, and on the surface of each source and drain in the periphery circuit region.

It is an advantage of the present invention that the method of the present invention for manufacturing a MOS transistor of an embedded memory involving a self-aligned silicide (salicide) process in periphery circuit region and a self-aligned-contact (SAC) process in he memory array area, fits the requirements of MOS with high access speed in the periphery circuit region and decreasing storage charge refresh times in the memory array area.

### BRIEF DESCRIPTION OF THE DRAWINGS

FIG. 1 to FIG. 5 are schematic diagrams of fabricating an embedded memory according to the prior art.

FIG. 6 to FIG. 13 are schematic diagrams of fabricating an embedded memory according to the present invention.

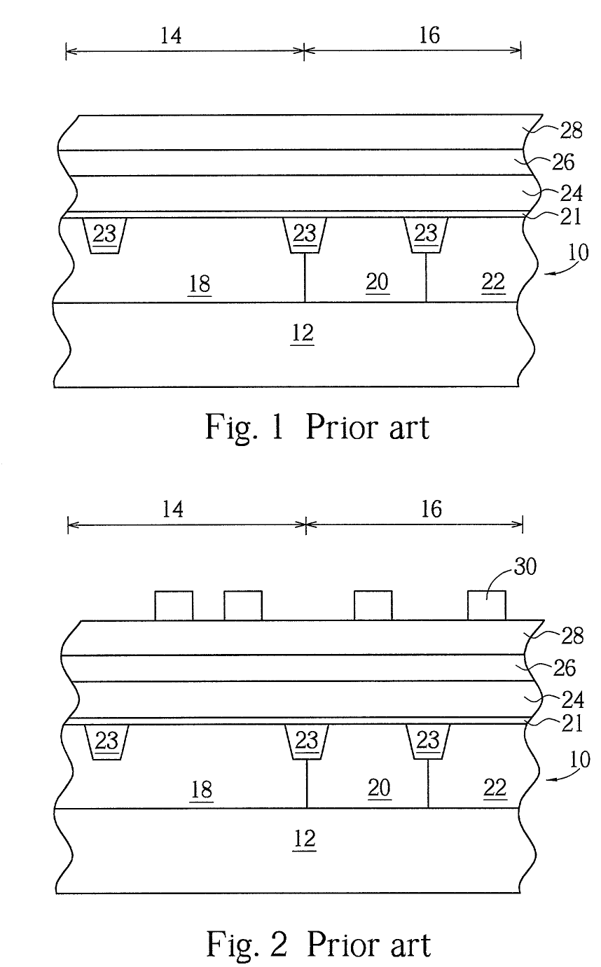

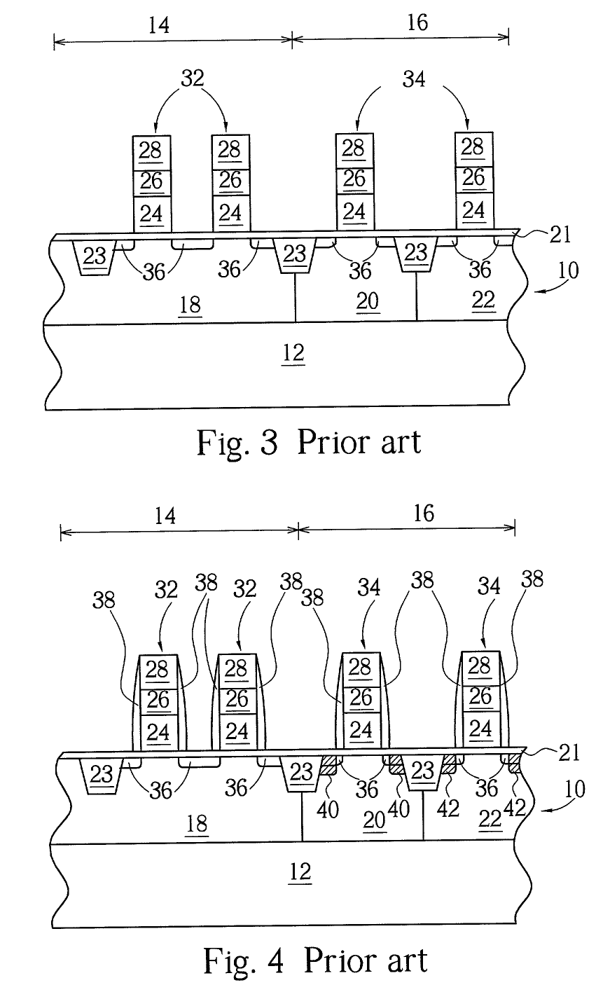

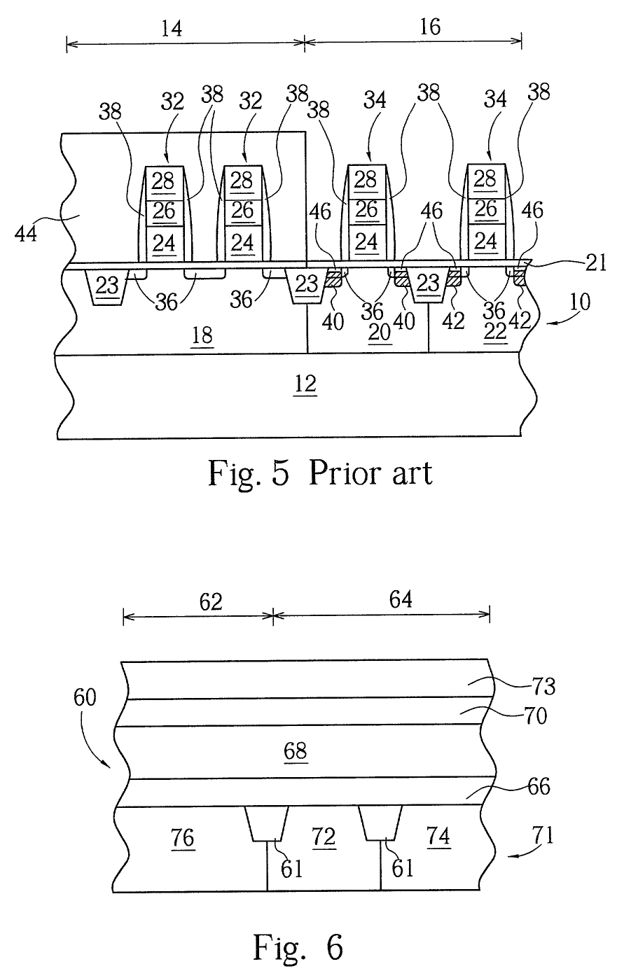

### DESCRIPTION OF THE PREFERRED EMBODIMENT

Please refer to FIG. 6 to FIG. 13. FIG. 6 to FIG. 13 are cross-sectional diagrams of the fabrication of a MOS transistor of an embedded memory on semiconductor wafer 60 according to the present invention. As shown in FIG. 6, a semiconductor wafer 60 has both a memory array area 62 and a periphery circuit region 64 defined on a surface of a silicon substrate 71. The memory array area 62 comprises at least one cell-well 76, and the periphery circuit region 64 comprises at least one N-well 72 and at least one P-well 74. Several shallow trench isolation (STI) structures 61 are formed to separate each region.

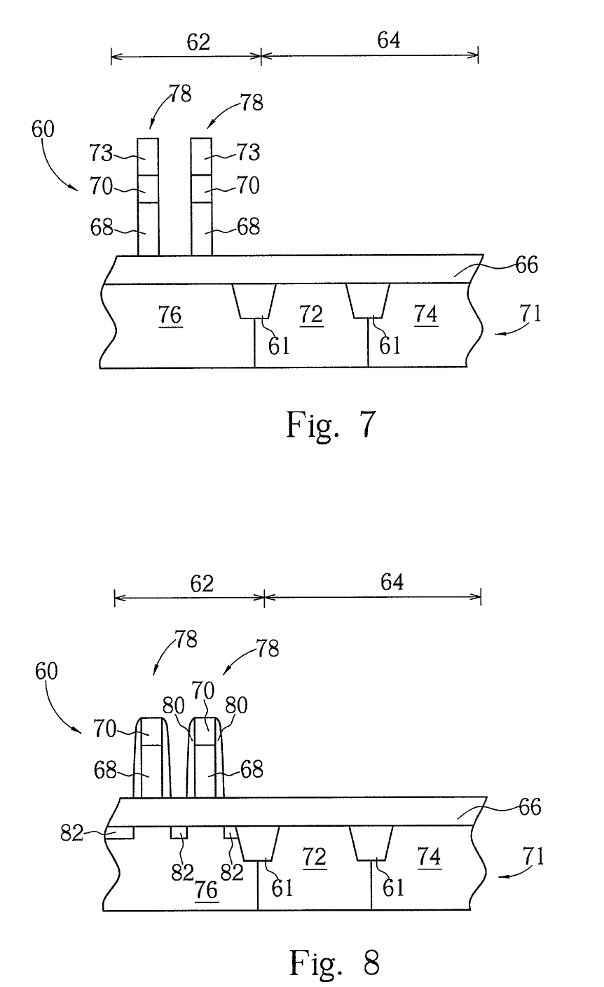

The present invention involves first forming a first dielectric layer 66, a doped polysilicon layer 68, a passivation layer 70, and a first photoresist layer 73 on the surface of semiconductor wafer 60. The dielectric layer 66 comprises silicon dioxide as an oxide layer of each gate. The passivation layer 70 comprises silicon nitride. A silicon-oxy-nitride (SiOₓN_{y}) layer (not shown) may be formed on the bottom of passivation layer 70 for serving as an anti-reflection coating (ARC) layer. The gate patterns in the photoresist layer 73 function as a hard mask for etching the passivation layer 70 and the doped polysilicon layer 68 located both in the memory array area 62 and in the periphery circuit region 64 down to the surface of the dielectric layer 66, so as to form each gate 78 in the memory array area 62. As shown in FIG. 7, the photoresist layer 73 is removed completely followed by forming a spacer 80 on sidewalls of each gate 78 in the memory array area 62. The spacer 80 comprises silicon nitride. As shown in FIG. 8, an ion implantation process is employed for forming a lightly doped drain (LDD) 82 surrounding each gate 78 in the memory array area 66.

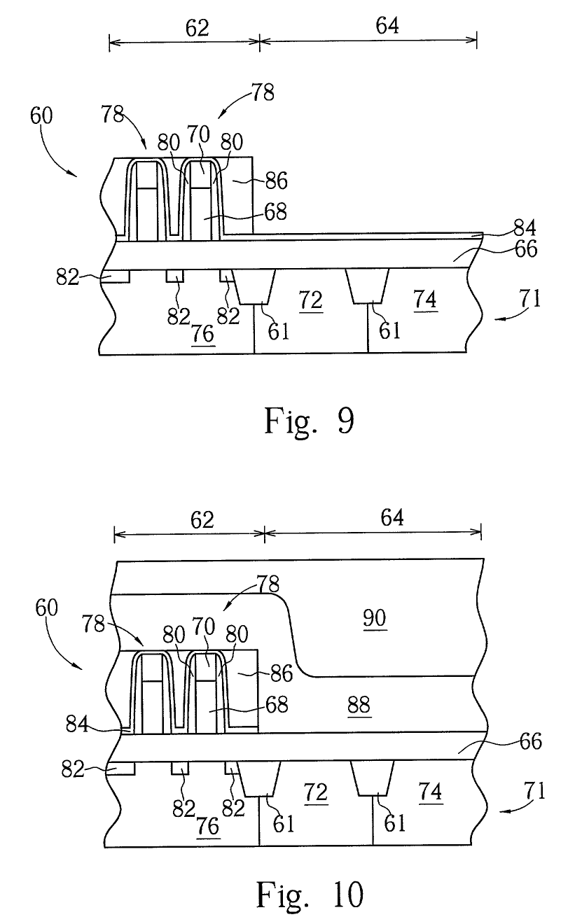

As shown in FIG. 9, a stop layer 84 comprising silicon nitride and a dielectric layer 86 is formed in sequence on the surface of the semiconductor wafer 60. An etch-back process is subsequently performed for removing the dielectric layer 86 and the stop layer 84 located in the periphery circuit region 64 for making dielectric layer 86 and the top surface of each gate 78 in the memory array area 66 with the same height.

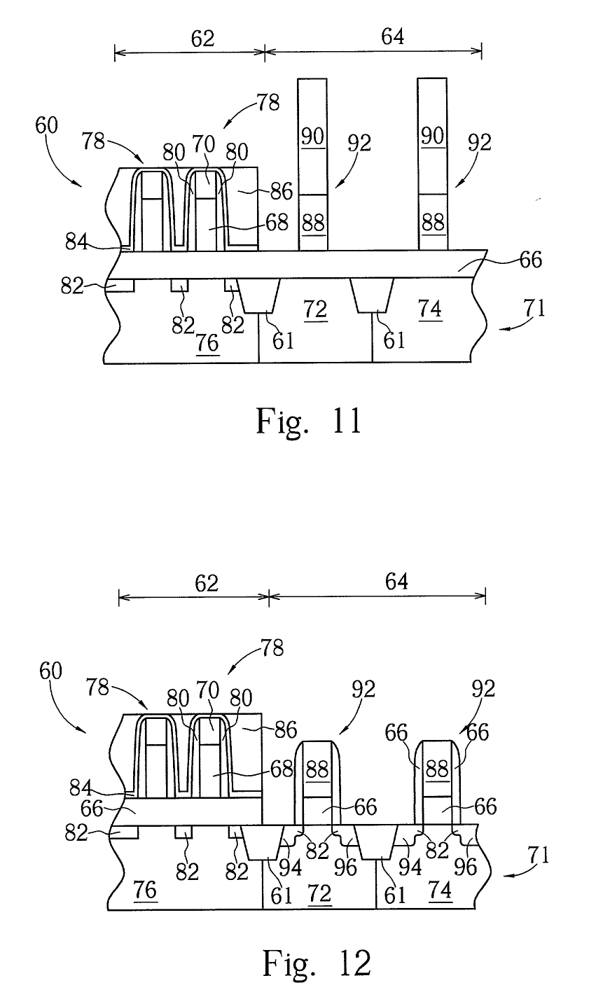

As shown in FIG. 10, the stop layer 84 located in the periphery circuit region 64 is removed followed by forming an undoped polysilicon layer 88 and a photoresist layer 90, in sequence, on the surface of the semiconductor wafer 60. Before photoresist layer 90 is formed, a silicon-oxy-nitride (SiOₓN_{y}) layer (not shown) may be formed on the surface of semiconductor wafer 60 to function as an anti-reflection coating (ARC) layer. Then, a photolithographic process defines a plurality of gate patterns in the photoresist layer 90 above the periphery circuit region 64. The gate patterns of the photoresist layer 90 are used as a hard mask to etch the undoped polysilicon layer 88 down to the surface of the dielectric layer 66 in the periphery circuit region 64 so as to form the gates in the periphery circuit region 64, as shown in FIG. 11.

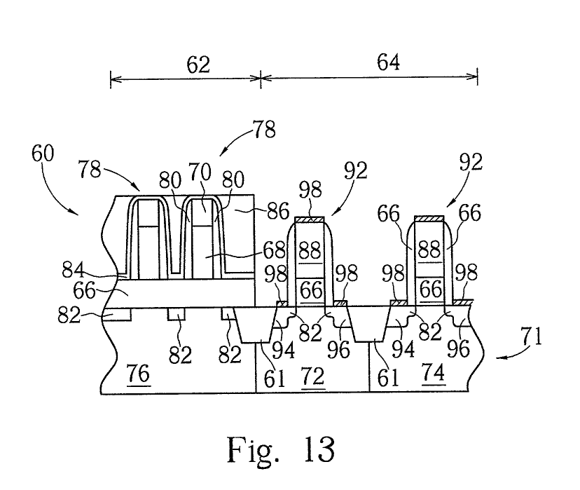

As shown in FIG. 12, after removing the photoresist layer 90 and the silicon-oxy-nitride (SiOₓN_{y}) under the photoresist layer 90, an ion implantation process forms a lightly doped drain (LDD) 82 surrounding each gate 92 in the periphery circuit region 64. A spacer 80 is formed on sidewalls of each gate 92 in the periphery circuit region 64. The spacer 80 comprises silicon nitride. A source 94 and a drain 96 are formed in sequence adjacent to each gate 92 in the periphery circuit region 64. An ion implantation process is performed on the source 94, the drain 96 and the undoped polysilicon layer 88 simultaneously for forming a PMOS transistor above a N-well and NMOS transistor above a P-well in the periphery circuit region 64.

As shown in FIG. 13, after the source 94 and the drain 96 of each MOS transistor are formed in the periphery circuit region 64, the metal layer (not shown) comprising Cobalt(Co) is formed subsequently on the surface of semiconductor wafer 60. The metal layer covers on each surface of the source 94, the drain 96 and the gate 92 in periphery circuit region 64. Then, a first rapid thermal process (RTP) with a temperature between 400° C. and 600° C. for 10 to 50 seconds forms a self-aligned silicide (salicide) layer 98 on the surface of the source 94, the drain 96 and the gate 92 in periphery circuit region 64. A wet etching process removes the metal layer that does not react with the surface of the semiconductor wafer 60. Finally, a second rapid thermal process (RTP) is performed at a temperature between 600° C. and 800° C. for a duration of 10 to 50 seconds. The Co₂Si and CoSi of the salicide layer 98 thus react to form CoSi₂, which has a lower resistance. Ti, Ni, or Mo can replace the Co that is used to form the metal layer.

The method of the present invention for manufacturing a MOS transistor of an embedded memory comprises forming a cap layer above the memory array area and a silicide layer on the surface of each source 94, drain 96 and gate 92 in periphery circuit region 64 so as to fit the requirements of a MOS with low resistance and high access speed in the periphery circuit region, and solve the problem of junction leakage current which can cause a more rapid loss of charge in the capacitor and increase storage charge refresh times.

Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A method for fabricating a metal oxide semiconductor (MOS)
transistor of an embedded memory, the method comprising:
providing a semiconductor wafer with both a memory array area and a periphery circuit region defined on the surface of a silicon substrate of the semiconductor wafer;
forming a first dielectric layer, a doped polysilicon layer, a passivation layer, and a first photoresist layer respectively on the surface of the semiconductor wafer;
performing a first photolithographic process so as to define a plurality of gate patterns in the first photoresist layer above the memory array area;
using the gate patterns in the first photoresist layer as a hard mask to etch the passivation layer and the doped polysilicon layer located both in the memory array area and in the periphery circuit region down to the surface of the first dielectric layer so as to form each gate in the memory array area;
removing the first photoresist layer; forming a spacer on sidewalls of each gate in the memory array area;
performing a first ion implantation process to form a lightly doped drain (LDD) adjacent to each gate in the memory array area;
forming a stop layer and a second dielectric layer in sequence on the surface of the semiconductor wafer;
performing an etch-back process to remove the second dielectric layer located in the periphery circuit region;
removing the stop layer located in the periphery circuit region;
forming an undoped polysilicon layer and a second photoresist layer in sequence on the surface of the semiconductor wafer;
performing a second photolithographic process to define a plurality of gate patterns in the second photoresist layer above the periphery circuit region;
using the gate patterns of the second photoresist layer as a hard mask to etch the undoped polysilicon layer down to the surface of the first dielectric layer so as to form the gates in the periphery circuit region;
removing the second photoresist layer;
performing a second ion implantation process to form a lightly doped drain (LDD) adjacent to each gate in the periphery circuit region;
forming a spacer on sidewalls of each gate in the periphery circuit region;
forming a source and a drain adjacent to each gate in the periphery circuit region; and
performing a self-aligned silicide (salicide) process to form a metal silicide layer respectively on the top surface of each gate, and on the surface of each source and drain in the periphery circuit region.

2. The method of claim 1 wherein the first dielectric layer is composed of silicon dioxide (SiO₂) and serves as the gate oxide layer for each gate.

3. The method of claim 1 wherein the passivation layer is composed of silicon nitride, and another silicon-oxy-nitride (SiOₓN_{y}) layer is formed at the bottom of the passivation layer, which serves as an anti-reflection coating (ARC) layer.

4. The method of claim 1 wherein each spacer is composed of silicon nitride.

5. The method of claim 1 wherein the stop layer is composed of silicon nitride.

6. The method of claim 1 wherein before forming the second photoresist layer on the surface of the semiconductor wafer, another silicon-oxy-nitride (SiOₓN_{y}) layer can be formed on the surface of the semiconductor wafer which serves as an ARC layer.

7. The method of claim 6 wherein after removing the second photoresist layer, the silicon-oxy-nitride (SiOₓN_{y}) layer formed under the second photoresist layer is also removed.

8. The method of claim 1 wherein the salicide process also comprises:
forming a metal layer on the surface of the semiconductor wafer, the metal layer covering the surfaces of the sources, the drains, and the gates in the periphery circuit region;
performing a first rapid thermal process (RTP);
removing the portions of the metal layer that do not react with the surface of the semiconductor wafer; and
performing a second rapid thermal process (RTP).

9. The method of claim 8 wherein the metal layer is composed of cobalt(Co), titanium(Ti), nickel(Ni), or molybdenum (Mo).

10. A method for fabricating a metal oxide semiconductor (MOS)
transistor of an embedded memory, the method comprising:
providing a semiconductor wafer with both a memory array area and a periphery circuit region defined on the surface of the silicon substrate of the semiconductor wafer, the memory array area comprising at least one cell-well, the periphery circuit region comprising at least one N-well and at least one P-well;
forming a first dielectric layer, a doped polysilicon layer, a passivation layer, and a first photoresist layer in sequence on the surface of the semiconductor wafer;
performing a first photolithographic process so as to define a plurality of gate patterns in the first photoresist layer above the cell-well of the memory array area;
using the gate patterns in the first photoresist layer as a hard mask to etch the passivation layer and the doped polysilicon layer located both in the memory array area and in the periphery circuit region down to the surface of the first dielectric layer so as to form each gate in the memory array area;
removing the first photoresist layer;
forming a first spacer on sidewalls of each gate in the memory array area;
performing a first ion implantation process to form a lightly doped drain (LDD) adjacent to each gate in the memory array area;
forming a stop layer and a second dielectric layer in sequence on the surface of the semiconductor wafer;
performing an etch-back process to remove the second dielectric layer located in the periphery circuit region;
removing the stop layer located in the periphery circuit region;
forming an undoped polysilicon layer and a second photoresist layer in sequence on the surface of the semiconductor wafer;
performing a second photolithographic process to define a plurality of gate patterns in the second photoresist layer above the N-well and P-well of the periphery circuit region;
using the gate patterns of the second photoresist layer as a hard mask to etch the undoped polysilicon layer down to the surface of the first dielectric layer so as to form the gates in the periphery circuit region;
removing the second photoresist layer;
performing a second ion implantation process to form a lightly doped drain (LDD) adjacent to each gate in the periphery circuit region;
forming a silicon nitride layer on the surface of the semiconductor wafer covering each gate in located in the periphery circuit region;
etching the silicon nitride layer adjacent to each gate on the P-well of the periphery circuit region to form a plurality of second spacers, and performing a third ion implantation process to form a source and a drain of each NMOS transistor within the P-well;
etching the silicon nitride layer adjacent to each gate on the N-well of the periphery circuit region to form a plurality of third spacers, and performing a fourth ion implantation process to form a source and a drain of each PMOS transistor within the N-well; and
performing a self-aligned silicide (salicide) process to respectively form a metal silicide layer on the top surface of each gate, and on the surface of each source and drain in the periphery circuit region.

11. The method of claim 10 wherein the first dielectric layer is composed of silicon dioxide (SiO₂) and serves as the gate oxide layer for each gate.

12. The method of claim 10 wherein the passivation layer is composed of silicon nitride, and another silicon-oxy-nitride (SiOₓN_{y}) layer is formed at the bottom of the passivation layer, which serves as an anti-reflection coating (ARC) layer.

13. The method of claim 10 wherein the first spacer is composed of silicon nitride.

14. The method of claim 10 wherein the stop layer is composed of silicon nitride.

15. The method of claim 10 wherein before forming the second photoresist layer on the surface of the semiconductor wafer, another silicon-oxy-nitride (SiOₓN_{y}) layer can be formed on the surface of the semiconductor wafer which serves as an ARC layer.

16. The method of claim 15 wherein after removing the second photoresist layer, the silicon-oxy-nitride (SiOₓN_{y}) layer formed under the second photoresist layer is also removed.

17. The method of claim 10 wherein the salicide process also comprises:
forming a metal layer on the surface of the semiconductor wafer, the metal layer covering the surfaces of the sources, the drains, and the gates in the periphery circuit region;
performing a first rapid thermal process (RTP);
removing the portions of the metal layer that do not react with the surface of the semiconductor wafer; and
performing a second rapid thermal process (RTP).

18. The method of claim 17 wherein the metal layer is composed of cobalt(Co), titanium(Ti), nickel(Ni), or molybdenum (Mo).
